(19) United States
(12) Patent Application Publication
(10) Pub. No.: US 2026/0129796 A1
(43) Pub. Date: May 7, 2026

(54) PIPELINE GUIDING MODULE, LIQUID COOLING DEVICE AND DATA PROCESSING SYSTEM

(71) Applicant: Wiwynn Corporation, New Taipei City (TW)

(72) Inventors: Chao-Yen Hu, New Taipei City (TW); Yan-Yu Chen, New Taipei City (TW)

(73) Assignee: Wiwynn Corporation, New Taipei City (TW)

(21) Appl. No.: 19/256,115

(22) Filed: Jun. 30, 2025

(30) Foreign Application Priority Data
Nov. 7, 2024 (TW) 113142647

(51) Int. Cl. H05K 7/20

(52) U.S. Cl. CPC H05K 7/20272; H05K 7/20254; H05K 7/20627; H05K 7/20763

(57) ABSTRACT

A pipeline guiding module includes a base, a floating member and a first elastic member. The base has an accommodating hole and a first restraining structure. The floating member is floatingly disposed in the accommodating hole. The first elastic member is disposed along an axial direction of the accommodating hole and sandwiched between the first restraining structure and the floating member. The pipeline guiding module may be applied to a liquid cooling device and a data processing system to offset a bending stress of a pipeline and avoid leakage at a connection between the pipeline and a connector.

### BACKGROUND OF THE INVENTION

### 1. Field of the Invention

The invention relates to a pipeline guiding module and, more particularly, to a pipeline guiding module capable of offsetting a bending stress of a pipeline, and a liquid cooling device and a data processing system equipped with the pipeline guiding module.

### 2. Description of the Prior Art

As the speed and performance of an electronic component (e.g. central processing unit) in a server increase, more and more servers use a liquid cooling manner to dissipate heat from the electronic component to improve heat dissipating efficiency. In general, a liquid cooling device occupies more space than an air cooling device. When the liquid cooling device is disposed in a limited space above the server, the following problems will occur due to insufficient space. When a distance between two connectors connecting a pipeline is too close, the pipeline is not easy to bend, such that leakage may easily occur at a connection between the pipeline and the connector. Furthermore, excessive bending stress of the pipeline may easily cause the connectors to fail to be assembled or even cause damage to the connectors.

### SUMMARY OF THE INVENTION

According to an embodiment of the invention, a pipeline guiding module comprises a base, a floating member and a first elastic member. The base has an accommodating hole and a first restraining structure. The floating member is floatingly disposed in the accommodating hole. The first elastic member is disposed along an axial direction of the accommodating hole and sandwiched between the first restraining structure and the floating member.

According to an embodiment of the invention, a liquid cooling device comprises a cold plate, the aforesaid pipeline guiding module and a pipeline connecting module. The pipeline guiding module is connected to the cold plate. The pipeline connecting module is connected to the pipeline guiding module.

According to an embodiment of the invention, a data processing system comprises a rack, a manifold, an electronic device and the aforesaid liquid cooling device. The manifold is disposed in the rack. The electronic device is disposed in the rack. The liquid cooling device is disposed on the electronic device. The pipeline connecting module is connected to the manifold.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic view illustrating a data processing system according to an embodiment of the invention.

FIG. 2 is a perspective view illustrating a liquid cooling device shown in FIG. 1.

FIG. 3 is a top view illustrating the liquid cooling device shown in FIG. 2.

FIG. 4 is a perspective view illustrating a pipeline guiding module shown in FIG. 2.

FIG. 5 is an exploded view illustrating the pipeline guiding module shown in FIG. 4.

FIG. 6 is a perspective view illustrating the pipeline guiding module shown in FIG. 2 from another viewing angle.

FIG. 7 is an exploded view illustrating the pipeline guiding module shown in FIG. 6.

FIG. 8 is a sectional view illustrating the pipeline guiding module shown in FIG. 2.

FIG. 9 is a sectional view illustrating a pipeline connecting module shown in FIG. 2.

### DETAILED DESCRIPTION

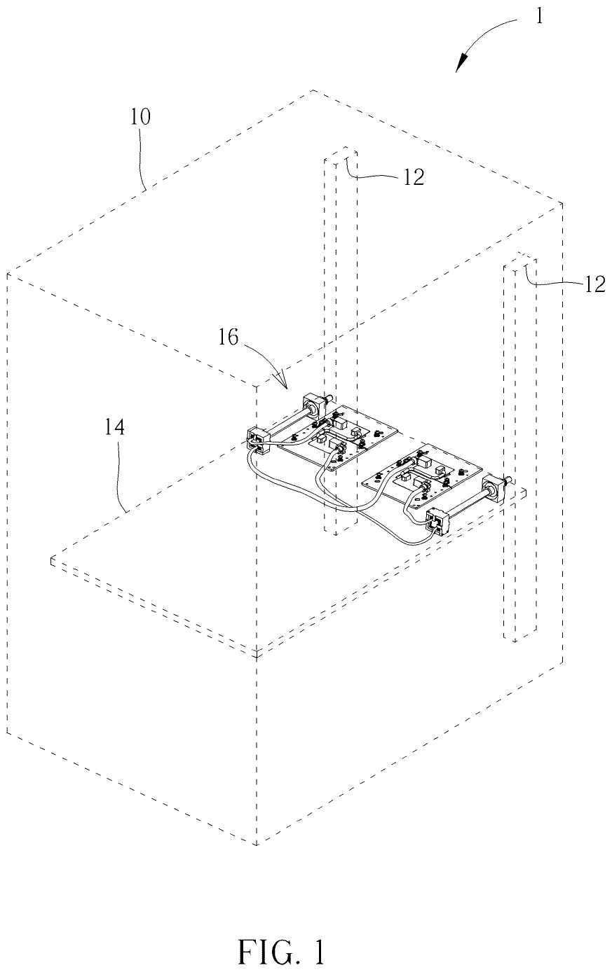

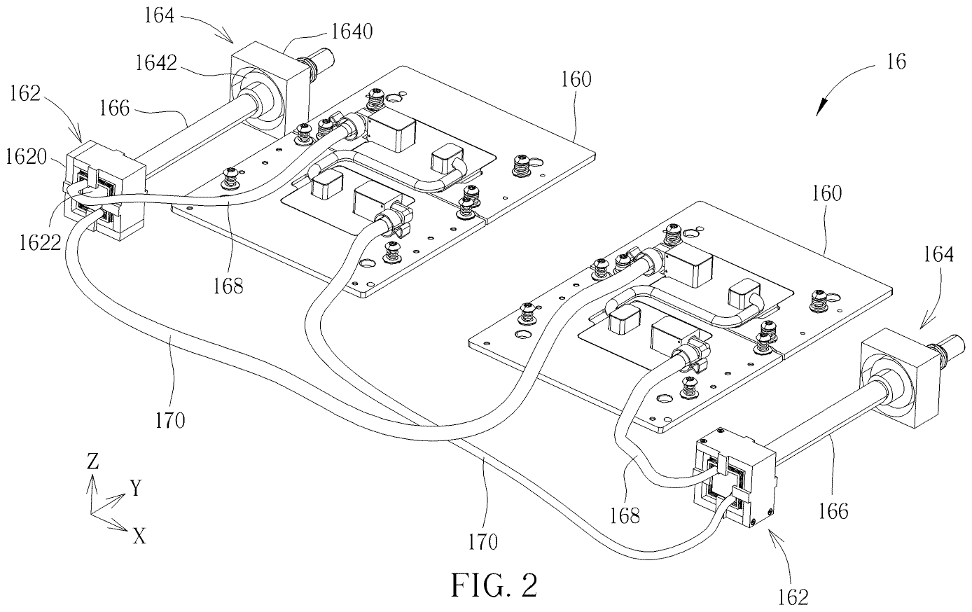

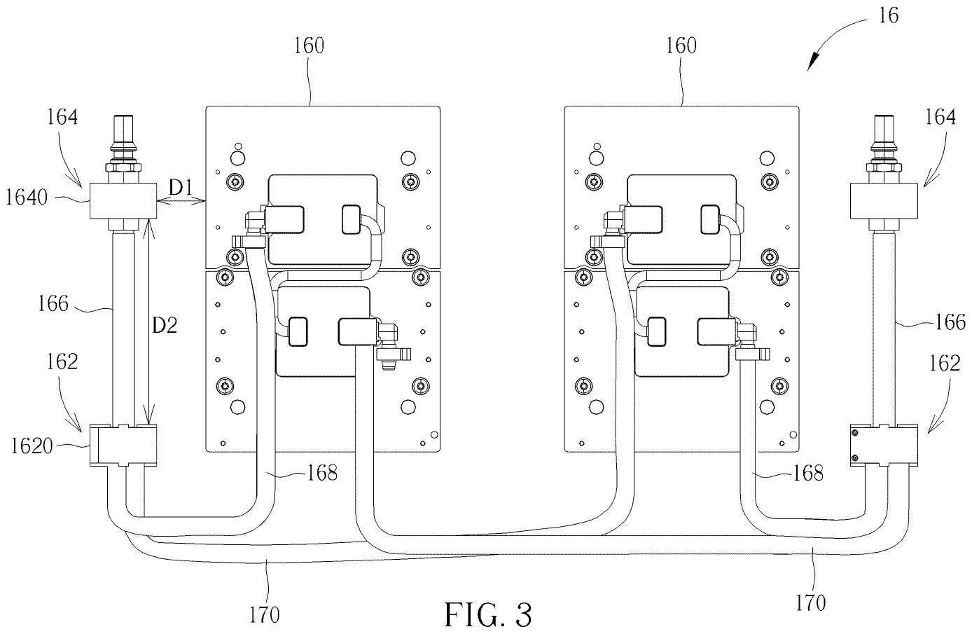

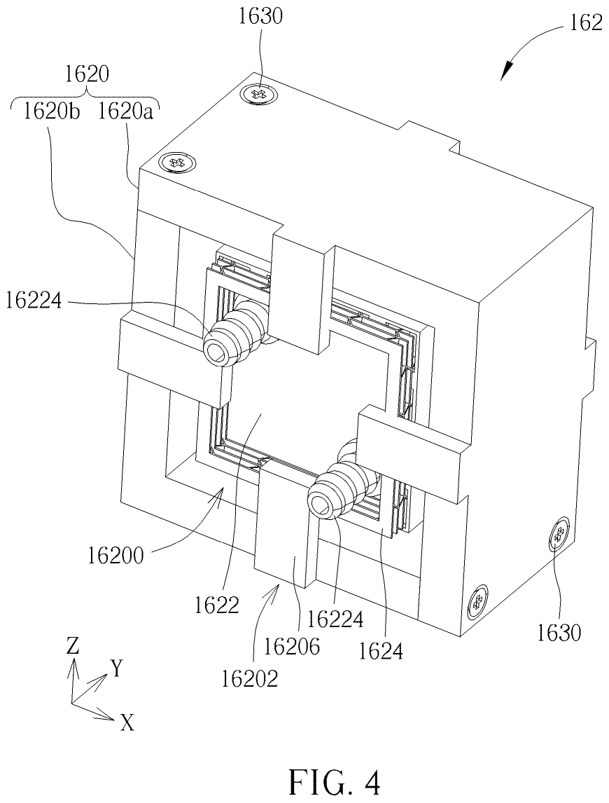

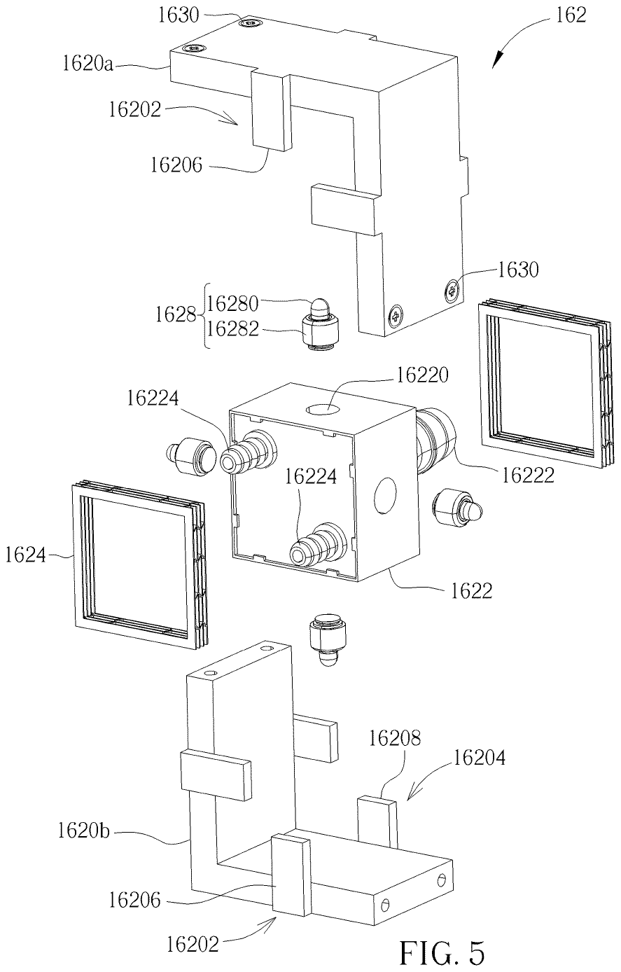

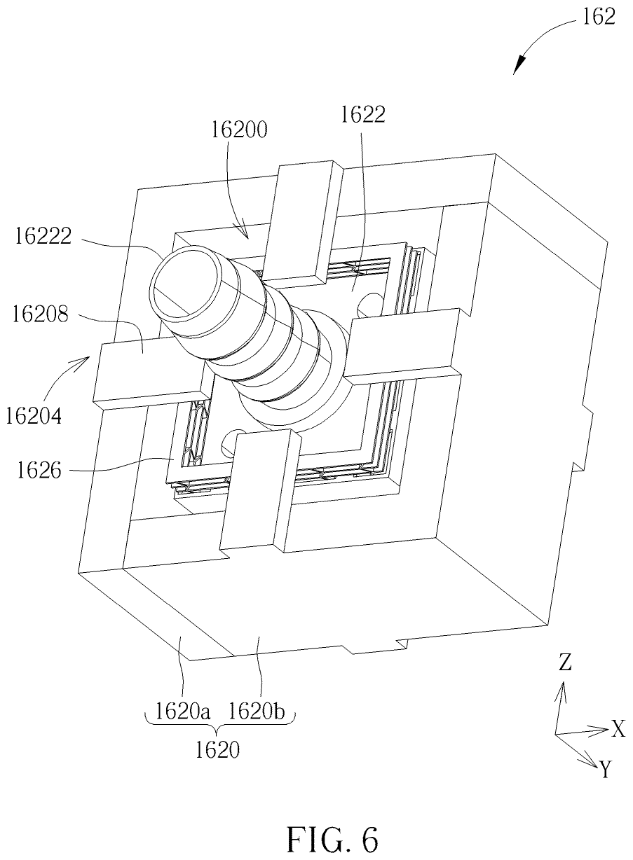

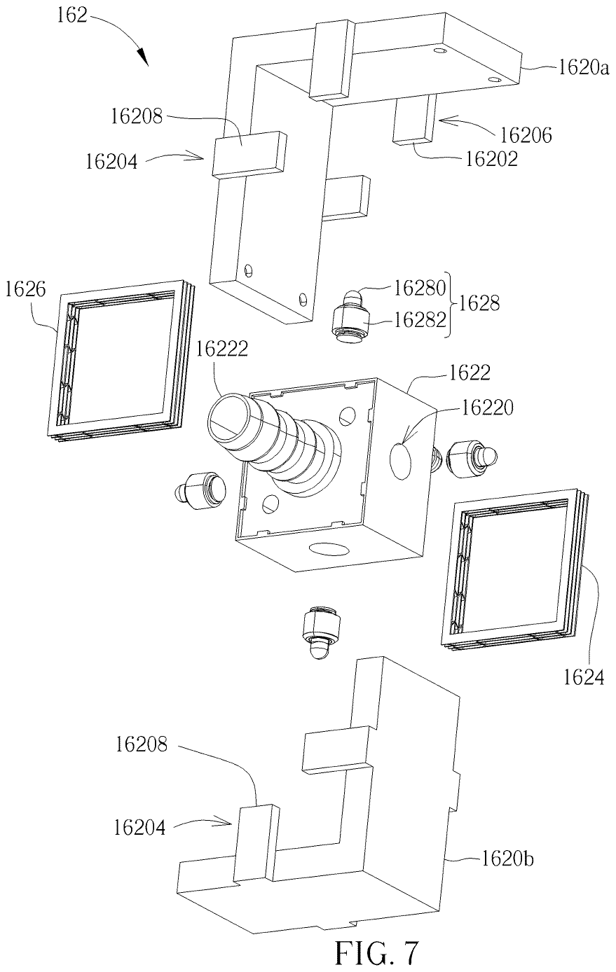

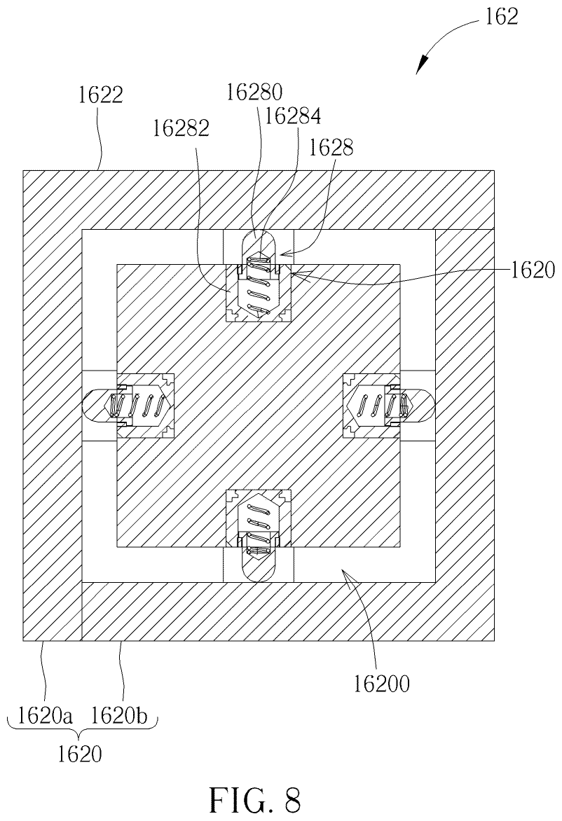

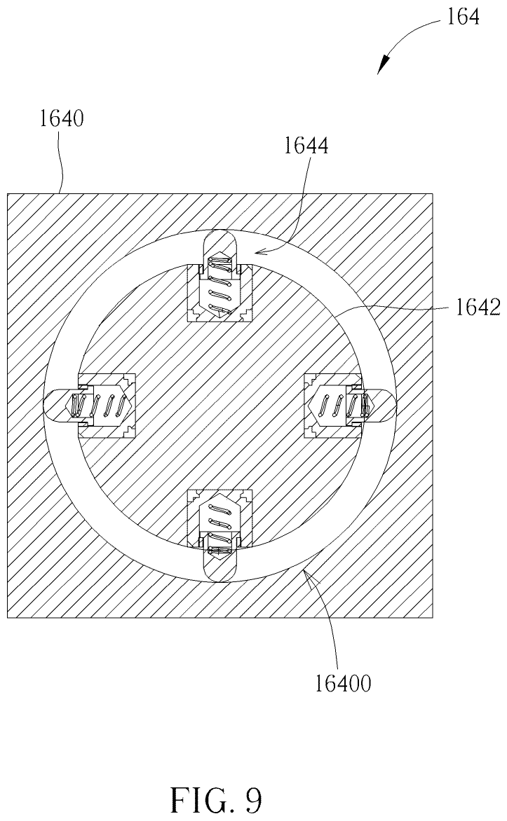

Referring to FIGS. 1 to 9, FIG. 1 is a schematic view illustrating a data processing system 1 according to an embodiment of the invention, FIG. 2 is a perspective view illustrating a liquid cooling device 16 shown in FIG. 1, FIG. 3 is a top view illustrating the liquid cooling device 16 shown in FIG. 2, FIG. 4 is a perspective view illustrating a pipeline guiding module 162 shown in FIG. 2, FIG. 5 is an exploded view illustrating the pipeline guiding module 162 shown in FIG. 4, FIG. 6 is a perspective view illustrating the pipeline guiding module 162 shown in FIG. 2 from another viewing angle, FIG. 7 is an exploded view illustrating the pipeline guiding module 162 shown in FIG. 6, FIG. 8 is a sectional view illustrating the pipeline guiding module 162 shown in FIG. 2, and FIG. 9 is a sectional view illustrating a pipeline connecting module 164 shown in FIG. 2.

As shown in FIG. 1, the data processing device 1 comprises a rack 10, a manifold 12, an electronic device 14 and a liquid cooling device 16. The manifold 12 and the electronic device 14 are disposed in the rack 10. The electronic device 14 may be a computer, a server or other electronic devices according to practical applications. The liquid cooling device 16 is disposed on the electronic device 14 and configured to dissipate heat from the electronic device 14. Furthermore, the liquid cooling device 16 is connected to the manifold 12, so as to exchange heat through the manifold 12. The manifold 12 may be connected to a cooling tank, a cooling distribution unit (CDU) and/or other liquid cooling components according to practical applications. In this embodiment, the data processing system 1 may comprise two manifolds 12 disposed at two sides of the rack 10, but the invention is not so limited. It should be noted that the number of the electronic devices 14 and the liquid cooling devices 16 may be determined according to practical applications, so the invention is not limited to the embodiment shown in the figure.

As shown in FIGS. 2 and 3, the liquid cooling device 16 comprises a cold plate 160, a pipeline guiding module 162 and a pipeline connecting module 164, wherein the pipeline guiding module 162 is connected to the cold plate 160, and the pipeline connecting module 164 is connected to the pipeline guiding module 162. When the liquid cooling device 16 is disposed in the rack 10 along with the electronic device 14, the pipeline connecting module 164 is connected to the manifold 12, such that the liquid cooling device 16 is able to exchange heat through the manifold 12. In this embodiment, the liquid cooling device 16 may comprise two cold plates 160, two pipeline guiding modules 162 and two pipeline connecting modules 164. Each of the two pipeline guiding modules 162 may be connected to the two cold plates 160 to be used as a flow divider. It should be noted that the number of the cold plates 160, the pipeline guiding modules 162 and the pipeline connecting modules 164 may be determined according to practical applications, so the invention is not limited to the embodiment shown in the figure.

As shown in FIGS. 4 to 7, the pipeline guiding module 162 comprises a base 1620, a floating member 1622, a first elastic member 1624, a second elastic member 1626 and a plurality of third elastic members 1628. The base 1620 has an accommodating hole 16200, a first restraining structure 16202 and a second restraining structure 16204, wherein the first restraining structure 16202 and the second restraining structure 16204 are located at opposite sides of the accommodating hole 16200. In this embodiment, the base 1620 may consist of two fixing blocks 1620a, 1620b, wherein the two fixing blocks 1620a, 1620b may be fixed with each other by a plurality of fixing members 1630 (e.g. screws), so as to restrain the floating member 1622 between the first restraining structure 16202 and the second restraining structure 16204. It should be noted that the fixing manner between the two fixing blocks 1620a, 1620b may be determined according to practical applications, so the invention is not limited to the embodiment shown in the figure. In this embodiment, the two fixing blocks 1620a, 1620b may be, but are not limited to, L-shaped. The shapes of the two fixing blocks 1620a, 1620b may be determined according to practical applications. In other embodiments, the base 1620 may be integrally formed or consist of four fixing blocks. The invention is not limited to the number of the fixing blocks.

The floating member 1622 is floatingly disposed in the accommodating hole 16200 of the base 1620. The first elastic member 1624 is disposed along an axial direction Y of the accommodating hole 16200 and sandwiched between the first restraining structure 16202 and the floating member 1622. The second elastic member 1626 is also disposed along the axial direction Y of the accommodating hole 16200 and sandwiched between the second restraining structure 16204 and the floating member 1622. Thus, the first elastic member 1624 and the second elastic member 1626 are located at opposite sides of the floating member 1622. At least one of the first elastic member 1624 and the second elastic member 1626 may be a wave spring. In this embodiment, the first elastic member 1624 and the second elastic member 1626 both are wave springs, but the invention is not so limited. Since the first elastic member 1624 and the second elastic member 1626 can elastically deform along the axial direction Y of the accommodating hole 16200, the first elastic member 1624 and the second elastic member 1626 enable the floating member 1622 to float forward and backward along the axial direction Y of the accommodating hole 16200.

In this embodiment, the first restraining structure 16202 may comprise a plurality of baffles 16206, wherein the baffles 16206 are symmetrically arranged at a periphery of the accommodating hole 16200. Similarly, the second restraining structure 16204 may comprise a plurality of baffles 16208, wherein the baffles 16208 are symmetrically arranged at the periphery of the accommodating hole 16200. The baffles 16206, 16208 may firmly clamp the first elastic member 1614, the floating member 1622 and the second elastic member 1626 in the accommodating hole 16200.

As shown in FIGS. 5, 7 and 8, the periphery of the floating member 1622 may have a plurality of fixing holes 16220. Each of the third elastic members 1628 may comprise a plunger 16280, a barrel 16282 and a spring 16284. The spring 16284 is disposed in the barrel 16282. The plunger 16280 is disposed at an end of the barrel 16282 and abuts against the spring 16284. Accordingly, the elastic deformation direction of the spring 16284 may be consistent with the direction of force, thereby preventing the spring 16284 from irregular twisting and deformation, so as to effectively increase the number of uses of the third elastic member 1628. Furthermore, the barrel 16282 of each of the third elastic members 1628 is fixed to one of the fixing holes 16220, and the plunger 16280 of each of the third elastic members 1628 abuts against the base 1620, such that the third elastic members 1628 are disposed at the periphery of the floating member 1622 along radial directions X, Z of the accommodating hole 16200 and abut against the base 1620. Since the third elastic members 1628 can elastically deform along the radial directions X, Z of the accommodating hole 16200, the third elastic members 1628 enable the floating member 1622 to float upward, downward, leftward and rightward along the radial directions X, Z of the accommodating hole 16200. In an embodiment, only one third elastic member 1628 may be provided in the radial directions X, Z respectively. It should be noted that the shape, size, number and position of the third elastic members 1628 may be determined according to practical applications, so the invention is not limited to the embodiment shown in the figure. Furthermore, the number and position of the fixing holes 16220 are determined according to the number and position of the third elastic members 1628.

For further explanation, the floating member 1622 is floatingly disposed in the accommodating hole 16200 of the base 1620 through the first elastic member 1624, the second elastic member 1626 and the third elastic members 1628, wherein the floating member 1622 may float along the axial direction Y and the radial directions X, Z of the accommodating hole 16200. In this embodiment, the first elastic member 1624 and the second elastic member 1626 are located at opposite sides of the floating member 1622, and the third elastic members 1628 are radially disposed at the periphery of the floating member 162, such that the floating member 1622 may move in any direction.

As shown in FIG. 9, the pipeline connecting module 164 may comprise a frame 1640, a floating block 1642 and a plurality of fourth elastic members 1644. The frame 1640 has an accommodating chamber 16400 and the floating block 1642 is floatingly disposed in the accommodating chamber 16400. In this embodiment, the periphery of the floating block 1642 may have a plurality of fixing holes 16420. The fourth elastic members 1644 are respectively fixed in the fixing holes 16420 and abut against the frame 1640. It should be noted that the structure and function of the fourth elastic member 1644 may the same as the structure and function of the third elastic member 1628, so the repeated explanation will not be depicted herein again. Thus, the floating block 1642 is floatingly disposed in the accommodating chamber 16400 of the frame 1640 through the fourth elastic members 1644.

As shown in FIGS. 2 and 3, the liquid cooling device 16 may further comprise a first pipeline 166, a second pipeline 168 and a third pipeline 170. The first pipeline 166 is connected to the floating member 1622 of the pipeline guiding module 162 and the floating block 1642 of the pipeline connecting module 164. The second pipeline 168 is connected to the cold plate 160 and the floating member 1622 of the pipeline guiding module 162. The third pipeline 170 is connected to another cold plate 160 and the floating member 1622 of the pipeline guiding module 162. In this embodiment, the liquid cooling device 16 may comprise two cold plates 160, two pipeline guiding modules 162, two pipeline connecting modules 164, two first pipelines 166, two second pipelines 168 and two third pipelines 170, but the invention is not so limited.

Furthermore, as shown in FIGS. 4 to 7, the floating member 1622 of the pipeline guiding module 162 may comprise a first pipeline connector 16222 and a plurality of second pipeline connectors 16224, wherein the first pipeline connector 16222 and the second pipeline connectors 16224 are located at opposite sides of the floating member 1622, and the first pipeline connector 16222 communicates with the second pipeline connectors 16224. In this embodiment, the floating member 1622 of the pipeline guiding module 162 may comprise two second pipeline connectors 16224 respectively connected to the second pipeline 168 and the third pipeline 170. Accordingly, the pipeline guiding module 162 may be connected to the two cold plates 160 to be used as a flow divider.

When the first pipeline 166, the second pipeline 168 and/or the third pipeline 170 are/is connected to the pipeline guiding module 162, the floating member 1622 may float under force, thereby offsetting the bending stress of the pipeline and avoiding leakage at the connection between the pipeline and the connector. Furthermore, since the floating member 1622 may float along three directions including the axial direction Y and the radial directions X, Z of the accommodating hole 16200, the floating block 1642 of the pipeline connecting module 164 may be kept at a central position to prevent the floating block 1642 (and the first pipeline connector 16222 and the second pipeline connectors 16224 thereon) from being eccentric due to the influence of the bending stress of the pipeline from any direction. Moreover, the floating block 1642 of the pipeline connecting module 164 may also float under force, such that the pipeline connecting module 164 is capable of absorbing assembly and/or manufacturing tolerances during assembly, thereby preventing the connectors from failing to be assembled or even being damaged.

As shown in FIG. 3, a distance D1 between the pipeline connecting module 164 and the cold plate 160 may be larger than or equal to 1 mm, and a distance D2 between the pipeline guiding module 162 and the pipeline connecting module 164 may be between 100 mm and 200 mm, such that the pipeline guiding module 162 may effectively offsetting the bending stress of the pipeline. It should be noted that the aforesaid distances D1, D2 may be determined according to practical applications, so the invention is not limited to the aforesaid embodiment.

As mentioned above, when the pipeline is connected to the pipeline guiding module, the floating member of the pipeline guiding module may float under force, thereby offsetting the bending stress of the pipeline and avoiding leakage at the connection between the pipeline and the connector. Furthermore, since the floating member may float along three directions, the floating block of the pipeline connecting module may be kept at the central position to prevent the floating block (and the first pipeline connector and the second pipeline connectors thereon) from being eccentric due to the influence of the bending stress of the pipeline from any direction. Moreover, the floating block of the pipeline connecting module may also float under force, such that the pipeline connecting module is capable of absorbing assembly and/or manufacturing tolerances during assembly, thereby preventing the connectors from failing to be assembled or even being damaged.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A pipeline guiding module comprising:
a base having an accommodating hole and a first restraining structure;
a floating member floatingly disposed in the accommodating hole; and
a first elastic member disposed along an axial direction of the accommodating hole and sandwiched between the first restraining structure and the floating member.

2. The pipeline guiding module of claim 1, wherein the base further has a second restraining structure, the first restraining structure and the second restraining structure are located at opposite sides of the accommodating hole, the pipeline guiding module further comprises a second elastic member, the second elastic member is disposed along the axial direction of the accommodating hole and sandwiched between the second restraining structure and the floating member, and the first elastic member and the second elastic member are located at opposite sides of the floating member.

3. The pipeline guiding module of claim 2, wherein at least one of the first elastic member and the second elastic member is a wave spring.

4. The pipeline guiding module of claim 1, further comprising a plurality of third elastic members disposed at a periphery of the floating member along a radial direction of the accommodating hole and abutting against the base.

5. The pipeline guiding module of claim 4, wherein each of the plurality of third elastic members comprises a plunger, a barrel and a spring, the spring is disposed in the barrel, and the plunger is disposed at an end of the barrel and abuts against the spring.

6. The pipeline guiding module of claim 5, wherein the periphery of the floating member has a plurality of fixing holes, the barrel of each of the plurality of third elastic members is fixed to one of the plurality of fixing holes, and the plunger of each of the plurality of third elastic members abuts against the base.

7. The pipeline guiding module of claim 1, wherein the floating member comprises a first pipeline connector and a plurality of second pipeline connectors, the first pipeline connector and the plurality of second pipeline connectors are located at opposite sides of the floating member, and the first pipeline connector communicates with the plurality of second pipeline connectors.

8. The pipeline guiding module of claim 1, wherein the first restraining structure comprises a plurality of baffles symmetrically arranged at a periphery of the accommodating hole.

9. A liquid cooling device comprising:
a cold plate;
the pipeline guiding module of claim 1 connected to the cold plate; and
a pipeline connecting module connected to the pipeline guiding module.

10. The liquid cooling device of claim 9, wherein the pipeline connecting module comprises a frame and a floating block, the frame has an accommodating chamber, the floating block is floatingly disposed in the accommodating chamber, the liquid cooling device further comprises a first pipeline and a second pipeline, the first pipeline is connected to the floating member and the floating block, and the second pipeline is connected to the cold plate and the floating member.

11. The liquid cooling device of claim 9, wherein a distance between the pipeline connecting module and the cold plate is larger than or equal to 1 mm.

12. The liquid cooling device of claim 9, wherein a distance between the pipeline guiding module and the pipeline connecting module is between 100 mm and 200 mm.

13. A data processing system comprising:
a rack;
a manifold disposed in the rack;
an electronic device disposed in the rack; and
the liquid cooling device of claim 9 disposed on the electronic device, the pipeline connecting module being connected to the manifold.
